(19) United States
(12) Patent Application Publication
(10) Pub. No.: US 2023/0197470 A1
(43) Pub. Date: Jun. 22, 2023

(54) SEMICONDUCTOR DEVICE AND SEMICONDUCTOR DEVICE MANUFACTURING METHOD

(71) Applicant: FUJI ELECTRIC CO., LTD., Kawasaki-shi (JP)

(72) Inventor: Takashi KATSUKI, Matsumoto-city (JP)

(73) Assignee: FUJI ELECTRIC CO., LTD., Kawasaki-shi (JP)

(21) Appl. No.: 17/975,422

(22) Filed: Oct. 27, 2022

(30) Foreign Application Priority Data
Dec. 17, 2021 (JP) 2021-204799

(51) Int. Cl. H01L 21/56; H01L 23/00; H01L 25/16; H01L 23/31; H01L 23/29; H01L 23/04

(52) U.S. Cl. CPC H01L 21/565; H01L 24/32; H01L 25/165; H01L 23/3142; H01L 23/295; H01L 23/04; H01L 24/48; H01L 24/73; H01L 2224/32225; H01L 2224/73265; H01L 2224/48137; H01L 2224/48225; H01L 2924/12031; H01L 2924/12032; H01L 2924/13091; H01L 2924/13055; H01L 2924/1811; H01L 2924/1815; H01L 2924/182; H01L 2924/18301; H01L 2924/186

(57) ABSTRACT

A semiconductor device, including a substrate having a mounting area on a front surface thereof, a semiconductor chip disposed in the mounting area, and an exterior member having a bottom surface bonded to the front surface of the substrate, the exterior member continuously surrounding the mounting area in a loop shape in a plan view of the semiconductor device, to thereby enclose a housing space, the mounting area being in the housing space. The semiconductor device further includes a sealing material sealing the housing space.

### CROSS-REFERENCE TO RELATED APPLICATION

This application is based upon and claims the benefit of priority of the prior Japanese Patent Application No. 2021-204799, filed on Dec. 17, 2021, the entire contents of which are incorporated herein by reference.

### BACKGROUND OF THE INVENTION

### 1. Field of the Invention

The embodiments discussed herein relate to a semiconductor device and a semiconductor device manufacturing method.

### 2. Background of the Related Art

A semiconductor device includes semiconductor chips and a substrate on which the semiconductor chips are disposed. Such semiconductor devices are used as power conversion devices, for example. The semiconductor chips include power elements. For example, the power elements are insulated gate bipolar transistors (IGBTs) and power metal oxide semiconductor field effect transistors (MOSFETs). The substrate includes an insulating plate and a plurality of circuit patterns formed on the front surface of the insulating plate.

In addition, in some semiconductor devices, semiconductor chips and a substrate are not accommodated in a case but are sealed with a sealing material. Such a semiconductor device is manufactured as follows. For example, a substrate on which semiconductor chips are disposed is set in the cavity of a hollow jig that is made of aluminum. A sealing material is injected into the cavity where the substrate is set, in order to seal the substrate. The substrate having the semiconductor chips disposed thereon, sealed with the sealing material, is taken out of the jig, thereby obtaining a semiconductor device. Before the substrate having the semiconductor chips disposed thereon is set in the jig, a mold-releasing sheet is placed in the cavity. This makes it easy to take out the semiconductor chips and substrate sealed with the sealing material from the cavity (see, for example, Japanese Laid-open Patent Publication No. 2015-73080).

However, in this semiconductor device manufacturing method, the use of the mold-releasing sheet in the cavity increases the cost. In addition, the mold-releasing sheet needs to adhere to the inner surface of the cavity. To this end, a step of forming through holes in the cavity and making a vacuum and a vacuum device are needed, which also increases the cost.

### SUMMARY OF THE INVENTION

According to one aspect, there is provided a semiconductor device, including: a substrate having a mounting area on a front surface thereof; a semiconductor chip disposed in the mounting area; an exterior member having a bottom surface bonded to the front surface of the substrate, the exterior member continuously surrounding the mounting area in a loop shape in a plan view of the semiconductor device, to thereby enclose a housing space, the mounting area being in the housing space; and a sealing material sealing the housing space.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a sectional view of a semiconductor device according to a first embodiment;

FIG. 2 is a plan view of the semiconductor device according to the first embodiment;

FIG. 3 is a plan view of the semiconductor device (except a sealing material) according to the first embodiment;

FIG. 4 is a flowchart of a semiconductor device manufacturing method according to the first embodiment;

FIG. 5 is a sectional view illustrating a semiconductor unit bonding step in the semiconductor device manufacturing method according to the first embodiment;

FIG. 6 is a plan view illustrating the semiconductor unit bonding step in the semiconductor device manufacturing method according to the first embodiment;

FIG. 7 is a sectional view illustrating the setting of a molding jig in the semiconductor device manufacturing method according to the first embodiment;

FIG. 8 is a plan view illustrating the setting of the molding jig in the semiconductor device manufacturing method according to the first embodiment;

FIG. 9 is a sectional view illustrating the injection of an exterior material in the semiconductor device manufacturing method according to the first embodiment;

FIG. 10 is a plan view illustrating the injection of the exterior material in the semiconductor device manufacturing method according to the first embodiment;

FIG. 11 is a sectional view of a semiconductor device according to a modification example 1-1 of the first embodiment;

FIG. 12 is a sectional view of a semiconductor device according to a modification example 1-2 of the first embodiment;

FIG. 13 is a sectional view of a semiconductor device according to a second embodiment;

FIG. 14 is a plan view of the semiconductor device according to the second embodiment;

FIG. 15 is a plan view of the semiconductor device (except a sealing material) according to the second embodiment;

FIG. 16 is a flowchart of a semiconductor device manufacturing method according to the second embodiment;

FIG. 17 is a sectional view (part 1) illustrating the setting of a molding jig in the semiconductor device manufacturing method according to the second embodiment;

FIG. 18 is a plan view (part 1) illustrating the setting of the molding jig in the semiconductor device manufacturing method according to the second embodiment;

FIG. 19 is a sectional view (part 2) illustrating the setting of the molding jig in the semiconductor device manufacturing method according to the second embodiment;

FIG. 20 is a plan view (part 2) illustrating the setting of the molding jig in the semiconductor device manufacturing method according to the second embodiment;

FIG. 21 is a sectional view illustrating the injection of an exterior material in the semiconductor device manufacturing method according to the second embodiment;

FIG. 22 is a sectional view (part 1) illustrating a sealing step and a demolding step in the semiconductor device manufacturing method according to the second embodiment; and

FIG. 23 is a sectional view (part 2) illustrating the sealing step and demolding step in the semiconductor device manufacturing method according to the second embodiment.

### DETAILED DESCRIPTION OF THE INVENTION

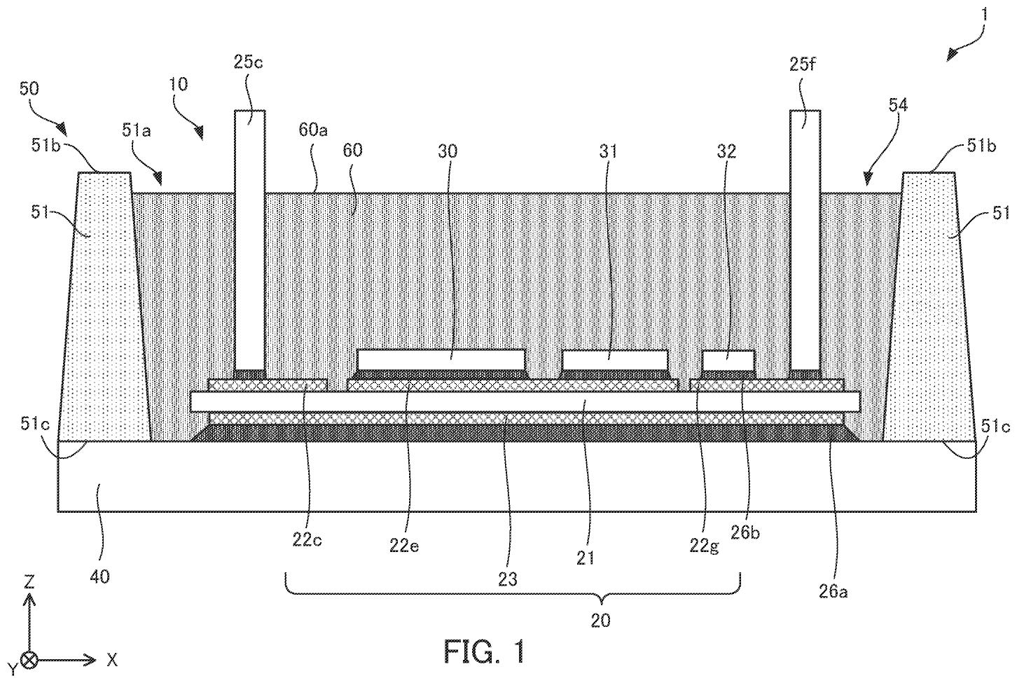

Hereinafter, embodiments will be described with reference to the accompanying drawings. In the following description, the terms “front surface” and “top surface” refer to X-Y surfaces facing upward (the +Z direction) in semiconductor device of FIGS. 1, 2, and 3. Similarly, the term “up” refers to the upward direction (the +Z direction) in the semiconductor device of FIGS. 1, 2, and 3. The terms “rear surface” and “bottom surface” refer to X-Y surfaces facing downward (the −Z direction) in the semiconductor device of FIGS. 1, 2, and 3. Similarly, the term “down” refers to the downward direction (the −Z direction) in the semiconductor device of FIGS. 1, 2, and 3. The same directionality applies to all drawings as needed. The term “higher level” refers to a position at a higher level (in the +Z direction) in the semiconductor device of FIGS. 1, 2, and 3. Similarly, the term “lower level” refers to a position at a lower level (in the −Z direction) in the semiconductor device of FIGS. 1, 2, and 3. The terms “front surface,” “top surface,” “up,” “rear surface,” “bottom surface,” “down,” and “side surface” are used for convenience to describe relative positional relationships, and do not limit the technical ideas of the embodiments. For example, the terms “up” and “down” are not always related to the vertical directions to the ground. That is, the “up” and “down” directions are not limited to the gravity direction. In addition, in the following description, the term “principal component” refers to a component contained at a volume ratio of 80 vol % or more.

### First Embodiment

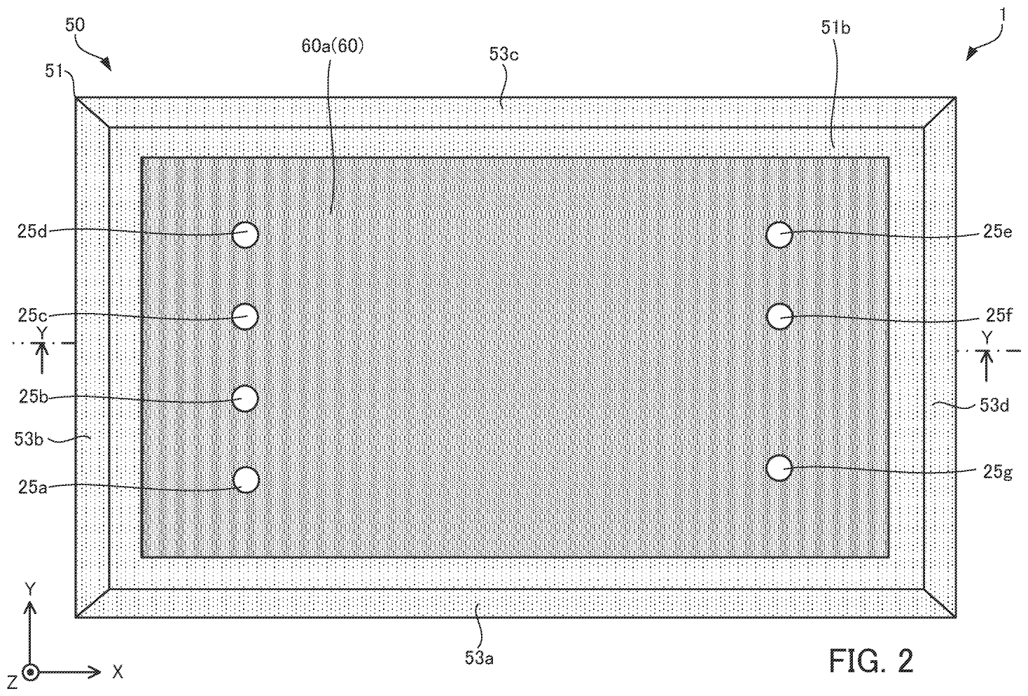

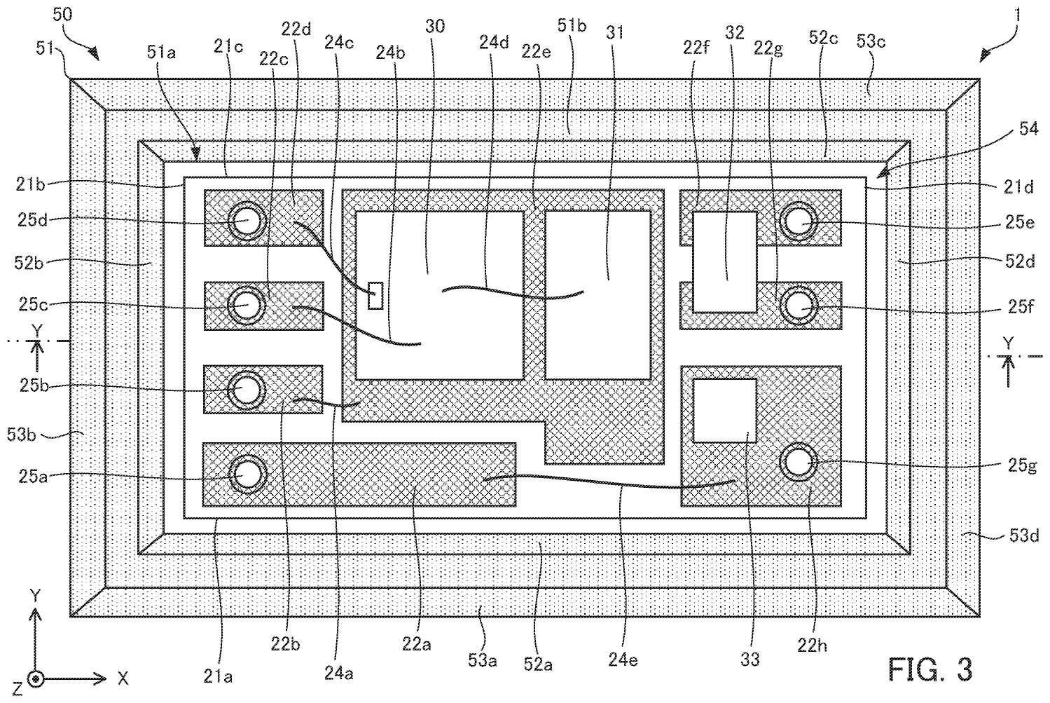

A semiconductor device according to a first embodiment will be described with reference to FIGS. 1 to 3. FIG. 1 is a sectional view of the semiconductor device according to the first embodiment, FIG. 2 is a plan view of the semiconductor device according to the first embodiment, and FIG. 3 is a plan view of the semiconductor device (except a sealing material) according to the first embodiment. In this connection, FIG. 1 is a sectional view taken along the dash-dotted line Y-Y of FIGS. 2 and 3. FIG. 3 is a plan view of the semiconductor device of FIG. 2 from which a sealing material 60 is removed.

The semiconductor device 1 includes a base substrate 40, a semiconductor unit 10, and an exterior member 50 surrounding the semiconductor unit 10, and the exterior member 50 has an opening 51a sealed with the sealing material 60. The semiconductor unit 10 includes an insulated circuit substrate 20, semiconductor chips 30 and 31, electronic parts 32 and 33, and external connection terminals 25a to 25g.

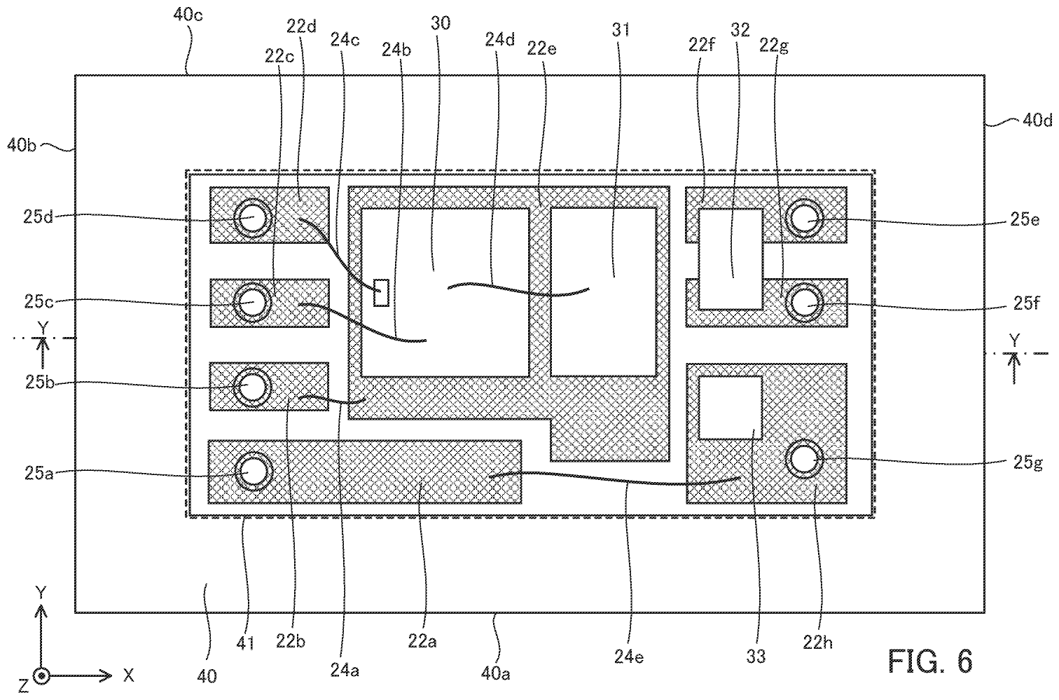

The base substrate 40 is rectangular in plan view, and is bounded by a base long side 40a, a base short side 40b, a base long side 40c, and a base short side 40d (see FIG. 6). The corners of the base substrate 40 may be rounded or chamfered. This base substrate 40 is made of a metal with high thermal conductivity. Examples of the metal include aluminum, iron, silver, copper, and an alloy containing at least one of these. Plating may be performed on the surface of the base substrate 40 to improve its corrosion resistance. Examples of the plating material used here include nickel, a nickel-phosphorus alloy, and a nickel-boron alloy. The semiconductor unit 10 is disposed at the center of the front surface of the base substrate 40. In this connection, the present embodiment describes the case where one semiconductor unit 10 is disposed on the base substrate 40. The arrangement is not limited thereto and a plurality of semiconductor units 10 may be disposed. In this case, the plurality of semiconductor units may be arranged in a line or in n rows and m columns, according to the number of semiconductor units 10.

The insulated circuit substrate 20 is rectangular in plan view. The insulated circuit substrate 20 includes an insulating plate 21, a plurality of circuit patterns 22a to 22h formed on the front surface of the insulating plate 21, and a metal plate 23 formed on the rear surface of the insulating plate 21. The outer shape of the plurality of circuit patterns 22a to 22h and the outer shape of the metal plate 23 are a little smaller than that of the insulating plate 21, and the plurality of circuit patterns 22a to 22h and the metal plate 23 are formed inside the insulating plate 21. In this connection, the shapes and quantity of the plurality of circuit patterns 22a to 22h are an example.

The insulating plate 21 is rectangular (oblong) in plan view. In addition, the corners of the insulating plate 21 may be chamfered or rounded. The insulating plate 21 is bounded by a long side 21a, short side 21b, long side 21c, and short side 21d that form the outer periphery thereof (see FIG. 3). The insulating plate 21 is made of ceramics with high thermal conductivity. For example, the ceramics are made from materials containing aluminum oxide, aluminum nitride, or silicon nitride as a principal component. In addition, for example, the insulating plate 21 may be made of a polymeric material as a principal component. The thickness of the insulating plate 21 is in the range of 0.1 mm to 2.0 mm, inclusive.

The circuit patterns 22a to 22h are formed on the entire front surface of the insulating plate 21 except the edge portion thereof. Preferably, in plan view, edges of the circuit patterns 22a to 22h facing the outer periphery of the insulating plate 21 are aligned with the corresponding edges of the metal plate 23 facing the outer periphery of the insulating plate 21. With this configuration, the insulated circuit substrate 20 maintains the stress balance between the circuit patterns 22a to 22h and the metal plate 23 on the rear surface of the insulating plate 21. Therefore, damage, such as excess warpage and cracks, to the insulating plate 21 is prevented. In addition, the thicknesses of the circuit patterns 22a to 22h are in the range of 0.1 mm to 2.0 mm, inclusive. The circuit patterns 22a to 22h are made of a metal with high electrical conductivity. Examples of the metal include copper, aluminum, and an alloy containing at least one of these. In addition, plating may be performed on the surfaces of the circuit patterns 22a to 22h to improve their corrosion resistance. Examples of the plating material used here include nickel, a nickel-phosphorus alloy, and a nickel-boron alloy. In this connection, the circuit patterns 22a to 22h are formed by forming a metal plate on the front surface of the insulating plate 21 and performing etching or another on the metal plate. Alternatively, the circuit patterns 22a to 22h cut out of a metal plate in advance may be press-bonded to the front surface of the insulating plate 21. In this connection, the circuit patterns 22a to 22h are just an example, and the quantity, shapes, sizes, and others of the circuit patterns may be determined as appropriate.

The circuit pattern 22a has an I shape in plan view. More specifically, the circuit pattern 22a extends along the long side 21a to the approximately center of the long side 21a on the side of the insulating plate 21 closer to the long side 21a. The circuit patterns 22b to 22d each have an I shape in plan view. The circuit patterns 22b to 22d are aligned along the short side 21b such that the sides of the circuit patterns 22b to 22d facing the short side 21b are in a straight line with the side of the circuit pattern 22a facing the short side 21b. Each circuit pattern 22b to 22d extends from a position closer to the short side 21b of the insulating plate 21 up to approximately one third of the long side 21a.

The circuit pattern 22e has an L shape in plan view. The circuit pattern 22e is formed at the center of the long side 21c on the side of the insulating plate 21 closer to the long side 21c. In addition, the circuit pattern 22a extends to a notch area of the circuit pattern 22e.

The circuit patterns 22f and 22g each have an I shape in plan view. The circuit patterns 22f and 22g are formed from the short side 21d of the insulating plate 21 along the long side 21c. The circuit patterns 22f and 22g each extend from a position closer to the short side 21d of the insulating plate 21 up to approximately one third of the long side 21a. The circuit pattern 22h is square in plan view. The length of the circuit pattern 22h is approximately equal to the length in the long side direction of each circuit pattern 22f and 22g. The circuit pattern 22h is formed between the circuit pattern 22g and the long side 21a.

The metal plate 23 is rectangular in plan view. In addition, the corners of the metal plate 23 may be chamfered or rounded, for example. The metal plate 23 is smaller in size than the insulating plate 21 and is formed on the entire rear surface of the insulating plate 21 except the edge portion thereof. The metal plate 23 is made of a metal with high thermal conductivity as a principal component. Examples of the metal include copper, aluminum, and an alloy containing at least one of these. The thickness of the metal plate 23 is in the range of 0.1 mm and 2.0 mm, inclusive. Plating may be performed on the surface of the metal plate 23 to improve its corrosion resistance. Examples of the plating material used here include nickel, a nickel-phosphorus alloy, and a nickel-boron alloy.

As the insulated circuit substrate 20 configured as above, a direct copper bonding (DCB) substrate, an active metal brazed (AMB) substrate, or a resin insulating substrate may be used, for example. The insulated circuit substrate 20 transfers heat generated by the to-be-described semiconductor chips 30 and 31 and electronic parts 32 and 33, through the circuit patterns 22e, 22f, 22g, and 22h, the insulating plate 21, and the metal plate 23 to the rear surface of the insulated circuit substrate 20 to dissipate the heat. This insulated circuit substrate 20 is bonded to the base substrate 40 via a bonding material 26a.

A lead-free solder is used as the bonding material 26a. For example, the lead-free solder contains any one of a tin-silver-copper alloy, a tin-zinc-bismuth alloy, a tin-copper alloy, and a tin-silver-indium-bismuth alloy as a principal component. In addition, the bonding material 26a may contain an additive. Examples of the additive include nickel, germanium, cobalt, and silicon. The bonding material 26a containing the additive exhibits improved wettability, gloss, and bond strength, which results in an improvement in the reliability. Alternatively, the bonding material 26a may be a sintered metal.

The semiconductor chips 30 and 31 are made of silicon, silicon carbide, or gallium nitride as a principal component. The semiconductor chips 30 include switching elements. Each switching element is an IGBT or a power MOSFET, for example. In the case where a semiconductor chip 30 is an IGBT, the semiconductor chip 30 has a collector electrode serving as a main electrode on the rear surface thereof and has a gate electrode serving as a control electrode and an emitter electrode serving as a main electrode on the front surface thereof. In the case where a semiconductor chip 30 is a power MOSFET, the semiconductor chip 30 has a drain electrode serving as a main electrode on the rear surface thereof and has a gate electrode serving as a control electrode and a source electrode serving as a main electrode on the front surface thereof.

The semiconductor chips 31 include diode elements. Each diode element is a free wheeling diode (FWD) such as a Schottky barrier diode (SBD) or a P-intrinsic-N (PiN) diode, for example. A semiconductor chip 31 of this type has a cathode electrode serving as a main electrode on the rear surface thereof and has an anode electrode serving as a main electrode on the front surface thereof.

The rear surfaces of the semiconductor chips 30 and 31 are bonded to the circuit pattern 22e using a bonding material 26b (see FIG. 1). The bonding material 26b may have the same composition as the bonding material 26a. In addition, the thicknesses of the semiconductor chips 30 and 31 are in the range of 180 μm to 220 μm, for example, and are approximately 200 μm on average.

Each electronic part 32 and 33 is a resistor, thermistor, capacitor, or surge absorber, for example. The electronic part 32 is bonded to the circuit patterns 22f and 22g using the bonding material 26b such as to lie over the gap between the circuit patterns 22f and 22g. The electronic part 33 is bonded to the circuit pattern 22h using the bonding material 26b.

Wires 24a to 24e are made of a material with high electrical conductivity, such as aluminum, copper, or an alloy containing at least one of these. In addition, the diameters of the wires 24a to 24e are preferably in the range of 100 μm to 1.0 mm, inclusive, for example. The wire 24a directly connects the circuit patterns 22b and 22e. The wire 24b directly connects the circuit pattern 22c and the main electrode on the front surface of the semiconductor chip 30. The wire 24c directly connects the circuit pattern 22d and the control electrode on the front surface of the semiconductor chip 30. The wire 24d directly connects the main electrode on the front surface of the semiconductor chip 30 and the main electrode on the front surface of the semiconductor chip 31. The wire 24e directly connects the circuit patterns 22a and 22h.

The external connection terminals 25a to 25g are made of a metal with high electrical conductivity. Examples of the metal include copper, aluminum, and an alloy containing at least one of these. In addition, plating may be performed on the surfaces of the external connection terminals 25a to 25g to improve their corrosion resistance. Examples of the plating material used here include nickel, a nickel-phosphorus alloy, and a nickel-boron alloy. The external connection terminals 25a to 25g have a columnar shape and, for example, have a rectangular or circular cross section. The heights of the external connection terminals 25a to 25g are greater than that of the to-be-described exterior member 50. The external connection terminals 25a to 25g may electrically be connected to the circuit patterns 22a to 22d and 22f to 22h via the bonding material 26b, respectively. Alternatively, the external connection terminals 25a to 25g may be press-inserted in the hollow holes of contact components (not illustrated), respectively, so as to be electrically connected to the circuit patterns 22a to 22d and 22f to 22h via the contact components. The external connection terminals 25a to 25g extend vertically upward with respect to the insulated circuit substrate 20.

The exterior member 50 includes a bank portion 51. The bank portion 51 has a frame shape in plan view. More specifically, the bank portion 51 is continuously formed in a loop shape along the base long side 40a, base short side 40b, base long side 40c, and base short side 40d of the base substrate 40. The bank portion 51 is formed of a thermosetting resin. Examples of the thermosetting resin include an epoxy resin, phenolic resin, maleimide resin, and polyester resin. The bank portion 51 is formed of a thermosetting resin with higher viscosity and lower melting point than the to-be-described sealing material 60. The bank portion 51 has a top surface 51b, a bottom surface 51c, inner surfaces 52a to 52d, and outer surfaces 53a to 53d.

The top surface 51b has a continuous loop shape in plan view. The top surface 51b has four portions that are parallel to the base long side 40a, base short side 40b, base long side 40c, and base short side 40d of the base substrate 40, respectively.

The bottom surface 51c is opposite to the top surface 51b and has a continuous loop shape in plan view as well. In addition, the bottom surface 51c has four portions that are parallel to the base long side 40a, base short side 40b, base long side 40c, and base short side 40d of the base substrate 40, respectively. The width of the bottom surface 51c is greater than that of the top surface 51b. The width here refers to a length in the direction from the inside to the outside of the exterior member 50 in plan view. The outer edges of the four portions of the bottom surface 51c are aligned with the outer periphery of the base substrate 40, without protruding therefrom. The bottom surface 51c of the bank portion 51 is directly bonded to the base substrate 40 without any adhesive material.

The inner surfaces 52a to 52d connect the inner edge of the top surface 51b and the inner edge of the bottom surface 51c. In addition, the inner surfaces 52a to 52d connect to one another. Connecting the top surface 51b and the bottom surface 51c in this manner, the inner surfaces 52a to 52d surround a housing space 54 housing the semiconductor unit 10 on the four sides (see FIG. 3). In addition, the inner surfaces 52a to 52d are inclined with respect to the front surface of the base substrate 40. The inclination angle is an obtuse angle with respect to the front surface of the base substrate 40. The inner surfaces 52a to 52d are smooth without parting lines or others.

The outer surfaces 53a to 53d connect the outer edge of the top surface 51b and the outer edge of the bottom surface 51c. In addition, the outer surfaces 53a to 53d connect to one another. The outer surfaces 53a to 53d connect the top surface 51b and the bottom surface 51c in this manner (see FIG. 3). In addition, the outer surfaces 53a to 53d are inclined with respect to the front surface of the base substrate 40. The inclination angle is an obtuse angle with respect to the front surface of the base substrate 40. The outer surfaces 53a to 53d are smooth without parting lines or others.

Therefore, the cross sections of the bank portion 51 in the X-Z plane and Y-Z plane become wider in the direction from the top toward the front surface of the base substrate 40 (in the −Z direction). In addition, the joints between the top surface 51b of the bank portion 51 and each outer surface 53a to 53d and the joints between the top surface 51b and each inner surface 52a to 52d may be rounded or chamfered. In addition, the joints between the inner surfaces 52a to 52d do not need to have the right angle, but may be curved. Similarly, the joints between the outer surfaces 53a to 53d may be rounded or chamfered. Also, the joints between each inner surface 52a to 52d and the base substrate 40 may be curved. In the case where the joints between each inner surface 52a to 52d and the base substrate 40 are curved, the sealing material 60 is able to completely fill the joint corners therebetween without air voids when the sealing material 60 is injected into the housing space 54.

The top surface 51b may partially be inclined or may be rough, as long as it is substantially parallel to the front surface of the base substrate 40. In addition, the inner surfaces 52a to 52d and outer surfaces 53a to 53d may partially be inclined, as long as they are substantially smooth.

The sealing material 60 seals the semiconductor unit 10 arranged in the housing space 54 surrounded by the exterior member 50. In this connection, the lower portions of the external connection terminals 25a to 25g are sealed with the sealing material 60. The upper portions of the external connection terminals 25a to 25g extend vertically upward from the sealing front surface 60a of the sealing material 60. The sealing material 60 may be a thermosetting resin. Examples of the thermosetting resin include an epoxy resin, a phenolic resin, a maleimide resin, and a polyester resin, and an epoxy resin is preferably used. The sealing material 60 may contain a filler. The filler is ceramics with electrical insulating and high thermal conductivity. Examples of the filler include silicon oxide, aluminum oxide, boron nitride, and aluminum nitride. The content of the filler in the whole sealing material 60 is in the range of 10 vol % to 70 vol %, inclusive. The sealing front surface 60a of the sealing material 60 is positioned at a level lower than the top surface 51b of the exterior member 50. That is, the front surface of the semiconductor device 1 is not level. In sectional view, the outer peripheral portion (the top surface 51b of the exterior member 50) of the front surface of the semiconductor device 1 projects more upward than the inside (the sealing front surface 60a) thereof.

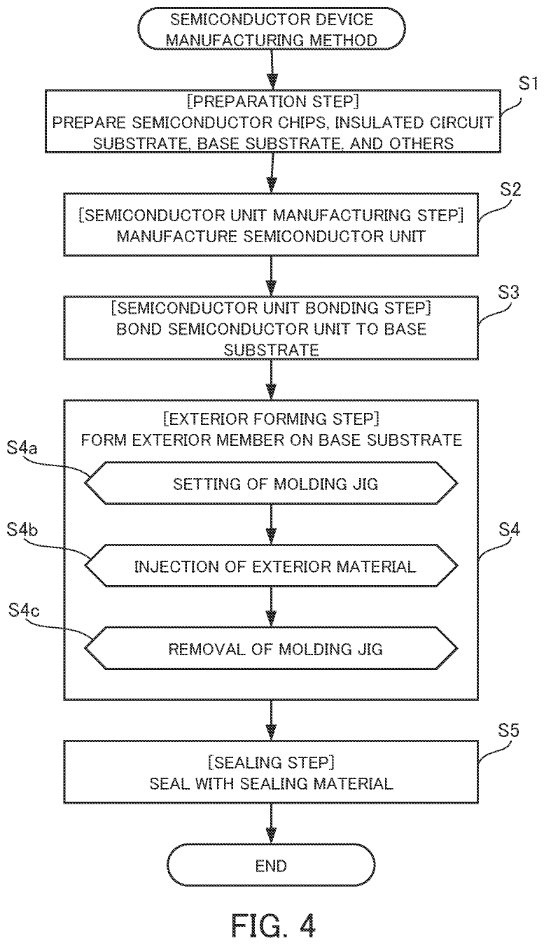

The following describes a method of manufacturing the semiconductor device 1 with reference to FIG. 4. FIG. 4 is a flowchart of a semiconductor device manufacturing method according to the first embodiment. First, a preparation step of preparing the components of the semiconductor device 1 is executed (step S1). The components of the semiconductor device 1 include the semiconductor chips 30 and 31, insulated circuit substrate 20, base substrate 40, electronic parts 32 and 33, and external connection terminals 25a to 25g. Other components needed for manufacturing the semiconductor device 1 may be prepared as well.

Then, a semiconductor unit manufacturing step of manufacturing the semiconductor unit 10 is executed (step S2). The insulated circuit substrate 20 is set in a predetermined manufacturing area for positioning, and a positioning jig is set on the insulated circuit substrate 20. The positioning jig includes openings corresponding to where the external connection terminals 25a to 25g, semiconductor chips 30 and 31, and electronic parts 32 and 33 are to be placed. Then, the external connection terminals 25a to 25g, semiconductor chips 30 and 31, and electronic parts 32 and 33 are set on the insulated circuit substrate 20 via a bonding material through the openings of the positioning jig. Then, heating is carried out to melt the bonding material, and then cooling is carried out to cool the molten bonding material, so that the external connection terminals 25a to 25g, semiconductor chips 30 and 31, and electronic parts 32 and 33 are bonded at the predetermined positions on the insulated circuit substrate 20. The positioning jig is then removed, thereby obtaining the semiconductor unit 10 illustrated in FIGS. 1 and 3.

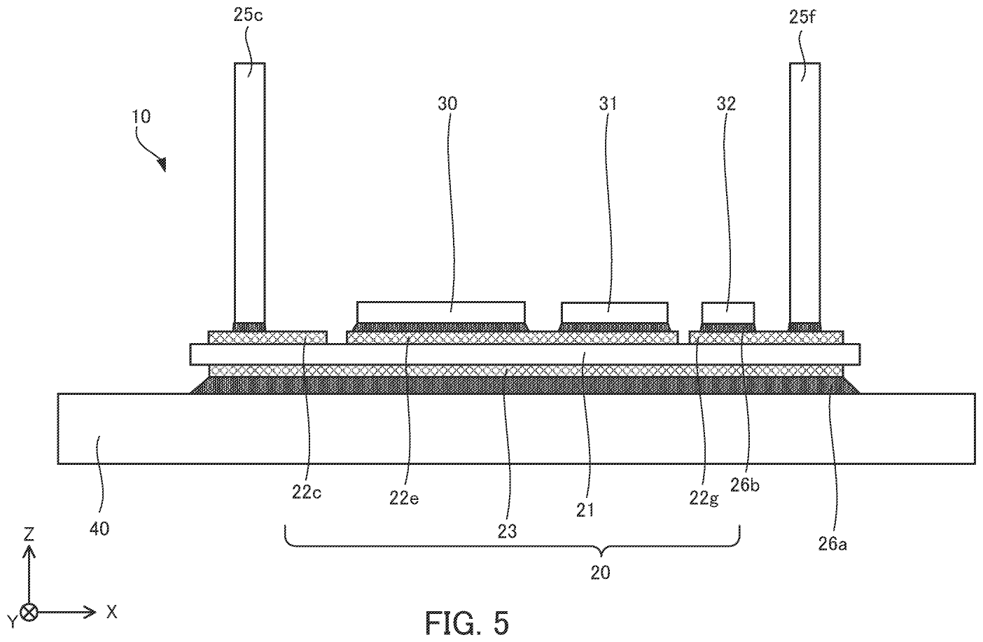

Then, a semiconductor unit bonding step of bonding the semiconductor unit 10 to the base substrate 40 is executed (step S3). The semiconductor unit bonding step will now be described with reference to FIGS. 5 and 6. FIG. 5 is a sectional view illustrating the semiconductor unit bonding step in the semiconductor device manufacturing method according to the first embodiment. FIG. 6 is a plan view illustrating the semiconductor unit bonding step in the semiconductor device manufacturing method according to the first embodiment. In this connection, FIG. 5 is a sectional view taken along the dash-dotted line Y-Y of FIG. 6.

A positioning jig having an opening corresponding to a mounting area 41 (enclosed by the broken line in FIG. 6) that is set for the semiconductor unit 10 at the center of the base substrate 40 is set. The semiconductor unit 10 is arranged via a bonding material through the opening of the positioning jig. Then, heating is carried out to melt the bonding material, and then cooling is carried out to cool the molten bonding material, so that the semiconductor unit 10 is bonded to the base substrate 40. The positioning jig is then removed, thereby obtaining the base substrate 40 having the semiconductor unit 10 bonded to the mounting area 41 of the front surface as illustrated in FIGS. 5 and 6.

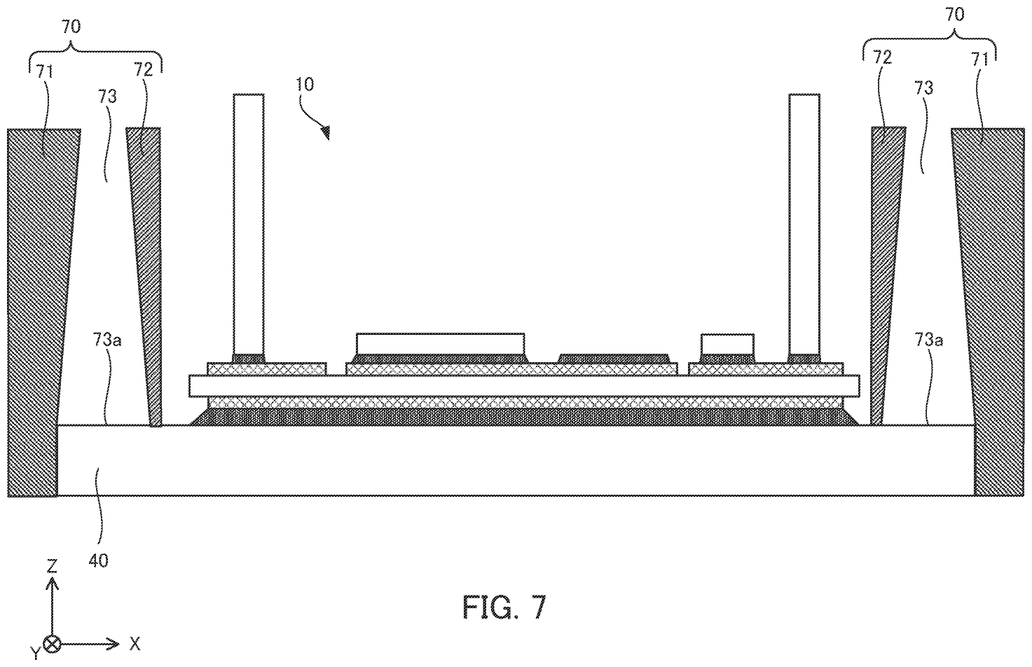

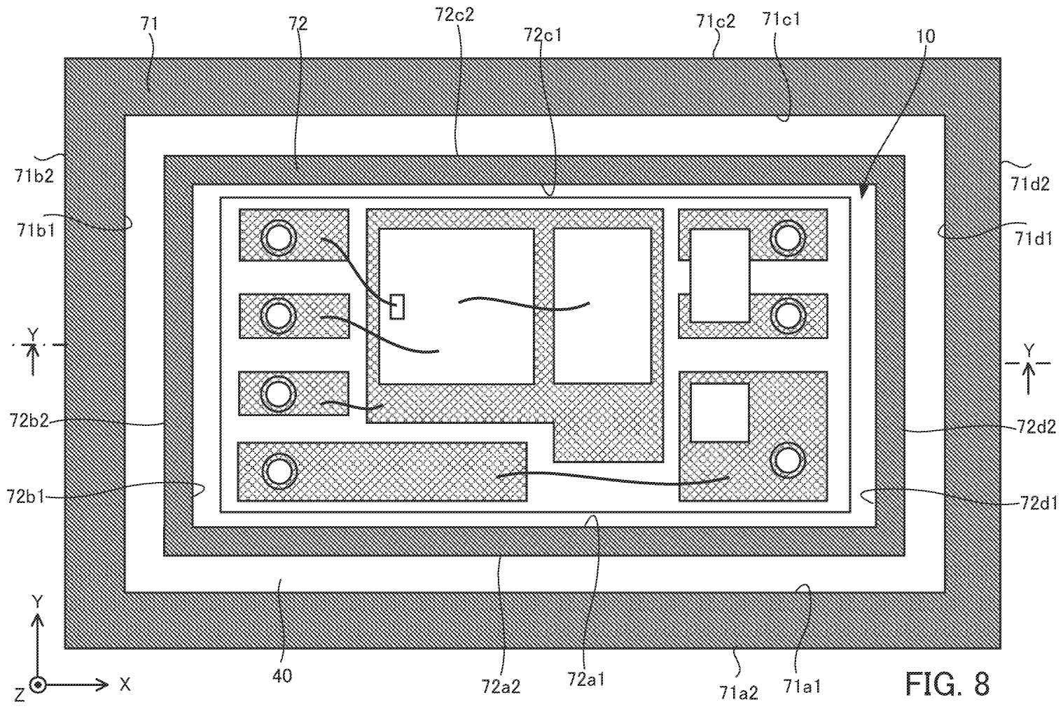

Then, an exterior forming step of forming the exterior member 50 around the semiconductor unit 10 on the base substrate 40 is executed (step S4). The exterior forming step includes steps S4a to S4c. First, a molding jig is set on the base substrate 40 (step S4a). Step S4a will be described with reference to FIGS. 7 and 8. FIG. 7 is a sectional view illustrating the setting of the molding jig in the semiconductor device manufacturing method according to the first embodiment. FIG. 8 is a plan view illustrating the setting of the molding jig in the semiconductor device manufacturing method according to the first embodiment. In this connection, FIG. 7 is a sectional view taken along the dash-dotted line Y-Y of FIG. 8.

As illustrated in FIGS. 7 and 8, the molding jig 70 is set outside the semiconductor unit 10 on the front surface of the base substrate 40 obtained at step S3. The molding jig 70 includes an outside molding portion 71 and an inside molding portion 72. The outside molding portion 71 and inside molding portion 72 demarcate a molding space 73. The molding jig 70 is made of a material with high heat resistance. Examples of this material include aluminum and carbon. The molding jig 70 may contain a releasing agent. Alternatively, the releasing agent may be applied to an area of the molding jig 70 that contacts a to-be-described exterior material.

The outside molding portion 71 has a frame shape. The outside molding portion 71 includes inside surfaces 71a1 to 71d1 and outside surfaces 71a2 to 71d2. The outside molding portion 71 contacts the base long side 40a, base short side 40b, base long side 40c, and base short side 40d of the base substrate 40 to enclose the base substrate 40.

The inside surfaces 71a1 to 71d1 enclose the base long side 40a, base short side 40b, base long side 40c, and base short side 40d. The portions of the inside surfaces 71a1 to 71d1 that contact the base long side 40a, base short side 40b, base long side 40c, and base short side 40d are perpendicular to the front surface of the base substrate 40. The portions of the inside surfaces 71a1 to 71d1 positioned at a level higher than the base long side 40a, base short side 40b, base long side 40c, and base short side 40d are inclined at an acute angle with respect to the front surface of the base substrate 40. The joints between the inside surfaces 71a1 to 71d1 at a level higher than the base substrate 40 may be curved. The joints between the inside surfaces 71a1 to 71d1 that contact the base substrate 40 may be curved to fit the corners of the base substrate 40.

The outside surfaces 71a2 to 71d2 are opposite to the inside surfaces 71a1 to 71d1, respectively. The outside surfaces 71a2 to 71d2 are parallel to the base long side 40a, base short side 40b, base long side 40c, and base short side 40d, respectively, and extend vertically upward. The outside surfaces 71a2 to 71d2 do not extend vertically upward, but may be inclined with respect to the front surface of the base substrate 40. The outside molding portion 71 may only have at least the inside surfaces 71a1 to 71d1.

The inside molding portion 72 has a frame shape. The inside molding portion 72 has inside surfaces 72a1 to 72d1 and outside surfaces 72a2 to 72d2. The inside molding portion 72 is arranged between the outside molding portion 71 and the semiconductor unit 10 on the base substrate 40 and surrounds the semiconductor unit 10. At this time, the outside surfaces 72a2 to 72d2 match the (inner) edge of the molding bottom surface 73a at the bottom of the molding space 73.

The inside surfaces 72a1 to 72d1 are provided along the base long side 40a, base short side 40b, base long side 40c, and base short side 40d, respectively, and extend vertically upward with respect to the front surface of the base substrate 40. Therefore, the inside surfaces 72a1 to 72d1 surround the semiconductor unit 10 on the four sides. The inside surfaces 72a1 to 72d1 may be perpendicular to the base substrate 40. Alternatively, the inside surfaces 72a1 to 72d1 may be inclined with respect to the base substrate 40. The joints between the inside surfaces 72a1 to 72d1 may be curved.

The outside surfaces 72a2 to 72d2 are opposite to the inside surfaces 72a1 to 72d1. The outside surfaces 72a2 to 72d2 are provided along the base long side 40a, base short side 40b, base long side 40c, and base short side 40d, respectively, and extend upward with respect to the front surface of the base substrate 40. The outside surfaces 72a2 to 72d2 are inclined at an acute angle with respect to the base substrate 40. The joints between the outside surfaces 72a2 to 72d2 may be rounded or chamfered.

As described above, the molding space 73 defined by the molding jig 70 is continuously formed in a loop shape along the outer periphery of the base substrate 40. In this connection, the height of the molding jig 70 may only be set greater than a desired height of the exterior member 50.

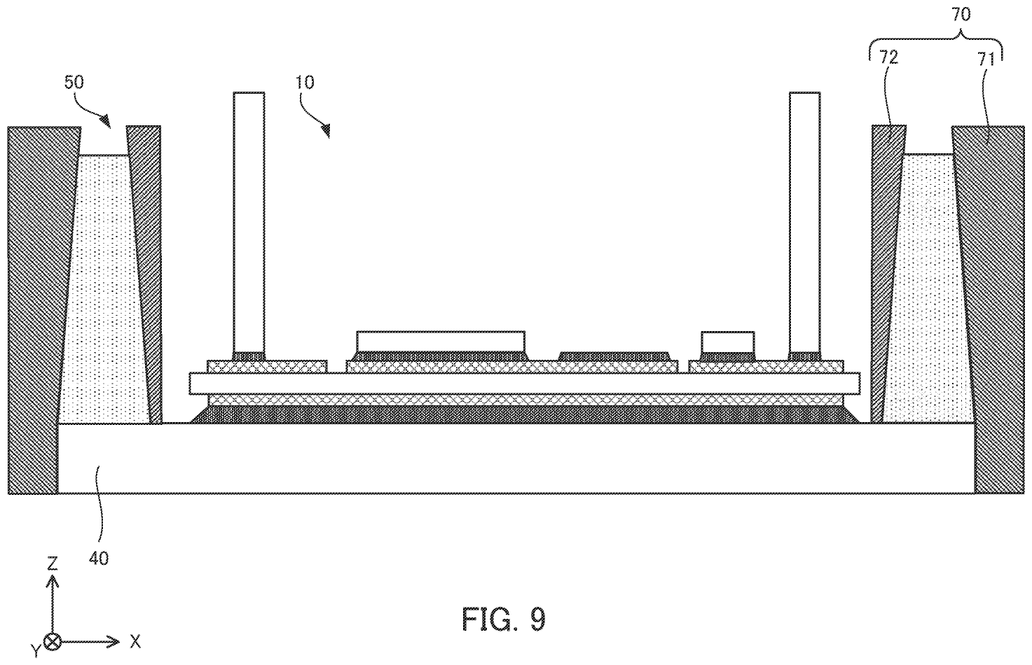

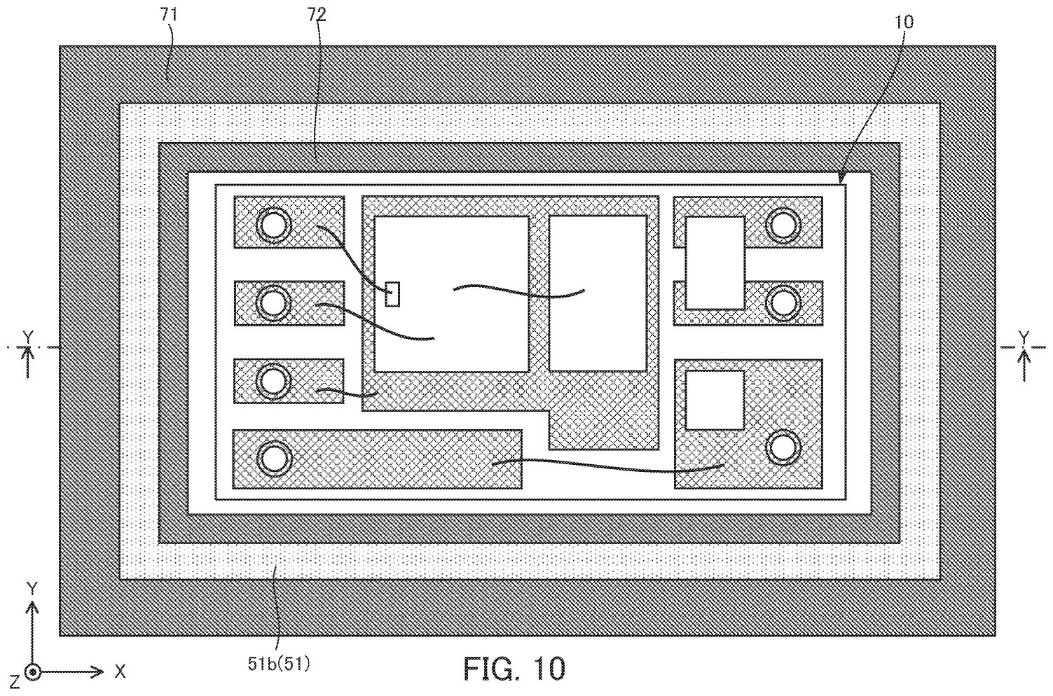

Then, an exterior material is injected in the molding jig 70 (step S4b). Step S4b will be described with reference to FIGS. 9 and 10. FIG. 9 is a sectional view illustrating the injection of the exterior material in the semiconductor device manufacturing method according to the first embodiment. FIG. 10 is a plan view illustrating the injection of the exterior material in the semiconductor device manufacturing method according to the first embodiment. In this connection, FIG. 9 is a sectional view taken along the dash-dotted line Y-Y of FIG. 10.

The exterior material is injected into the molding space 73 of the molding jig 70 attached at step S4a. The exterior material has the same composition as the exterior member 50. The exterior material fills the molding space 73 without air voids, as illustrated in FIGS. 9 and 10. The exterior material tends to descend due to its weight. The inside surfaces 71a1 to 71d1 of the outside molding portion 71 of the molding jig 70 and the outside surfaces 72a2 to 72d2 of the inside molding portion 72 thereof are each inclined at an acute angle with respect to the front surface of the base substrate 40. Therefore, the exterior material is able to stably fill the molding space 73 that becomes wider toward the base substrate 40. Therefore, the exterior material filling the molding space 73 is able to be solidified reliably. The exterior member 50 obtained by the solidification is hard and stable. In addition, the exterior material injected in this manner adheres to the base substrate 40 as it is. The exterior member 50 formed in this manner is directly bonded to the base substrate 40.

Then, the molding jig 70 is removed (step S4c). After the exterior material filling the molding space 73 is solidified to become the exterior member 50, the molding jig 70 is removed. The inner surfaces 52a to 52d and outer surfaces 53a to 53d of the exterior member 50 are each inclined at an obtuse angle with respect to the front surface of the base substrate 40. In addition, the outside surfaces 72a2 to 72d2 of the inside molding portion 72 and the inside surfaces 71a1 to 71d1 of the outside molding portion 71 are transcribed to the inner surfaces 52a to 52d and the outer surfaces 53a to 53d of the exterior member 50 formed in this manner. Therefore, the inner surfaces 52a to 52d and outer surfaces 53a to 53d of the exterior member 50 are smooth, without parting lines or others.

Then, a sealing step of sealing with the sealing material 60 is executed (step S5). The sealing material 60 is injected into the housing space 54 of the exterior member 50 formed at step S4. Thereby, the semiconductor unit 10 surrounded by the exterior member 50 is sealed. By solidifying the sealing material 60, the semiconductor device 1 illustrated in FIGS. 1 and 2 is obtained.

The above-described semiconductor device 1 includes the semiconductor chips 30 and 31, the base substrate 40 where the semiconductor chips 30 and 31 are disposed in the mounting area 41 on the front surface, the exterior member 50 whose bottom surface 51c is bonded to the front surface of the base substrate 40 and which continuously surrounds the mounting area 41 in a loop shape in plan view, and the sealing material 60 sealing the housing space 54 including the mounting area 41 surrounded by the exterior member 50. In this semiconductor device 1, the exterior member 50, as a substitute for a case, is formed without using any mold-releasing sheet. In addition, holes for making a vacuum do not need to be formed, and a vacuum step or vacuum device is not needed accordingly. It is possible to form the exterior member 50 at a predetermined position on the base substrate 40 with precision. The exterior member 50 is directly bonded to the base substrate 40. Therefore, an additional adhesive member, which may be needed if a case is used, is not needed, and an application step of applying the adhesive material is not needed accordingly. As a result, the semiconductor device 1 without a case is manufactured at reduced cost.

### Modification Example 1-1

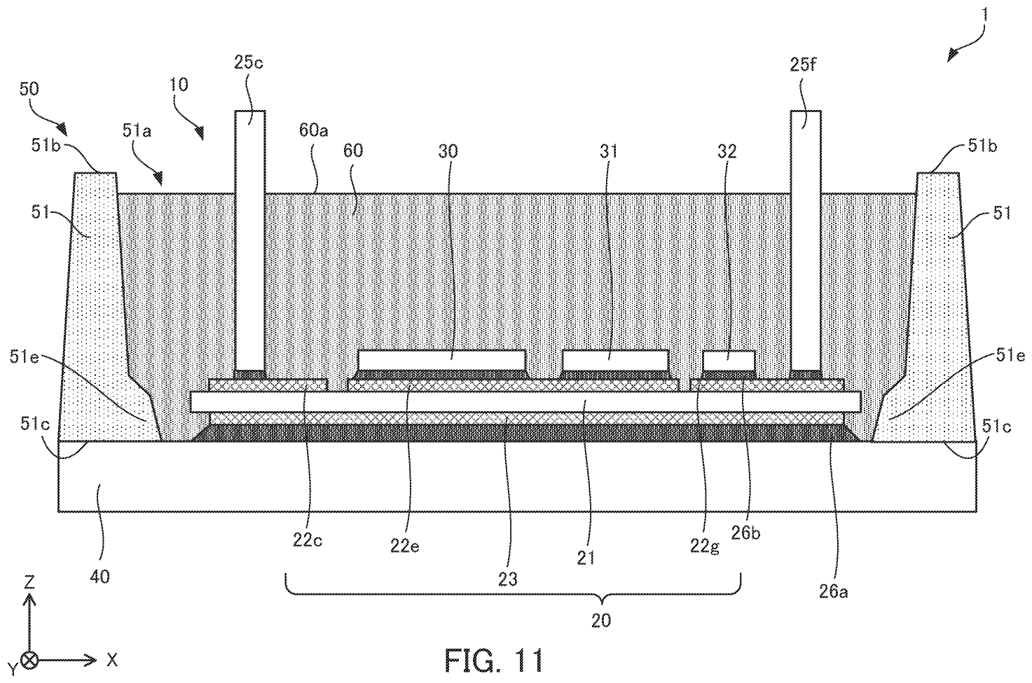

A modification example 1-1 describes an exterior member 50 different from that of FIGS. 1 to 3, with reference to FIG. 11. FIG. 11 is a sectional view of a semiconductor device according to the modification example 1-1 of the first embodiment. In this connection, as in FIG. 1, FIG. 11 corresponds to the sectional view taken along the dash-dotted line Y-Y of FIG. 3. In addition, the same reference numerals as used in the semiconductor device 1 of the first embodiment are given to the corresponding components, and the description of these components will be omitted or simplified.

The exterior member 50 of the semiconductor device 1 according to the modification example 1-1 has, on the lower inner surface thereof (on the side closer to the base substrate 40), a thickened portion 51e that is thicker than the lower portion of the exterior member 50 of the semiconductor device 1 illustrated in FIGS. 1 to 3.

This thickened portion 51e is continuously formed in a loop shape along the inner surfaces 52a to 52d of the bank portion 51. In other words, the lower portions of the inner surfaces 52a to 52d of the bank portion 51 on the side closer to the bottom surface 51c project more toward the semiconductor unit 10 than the upper portions thereof on the side closer to the top surface 51b. In this connection, the inner surfaces at the thickened portion 51e of the bank portion 51 are inclined at the same inclination angles as the inner surfaces 52a to 52d, respectively. In addition, the inner surfaces at the thickened portion 51e are smooth. This exterior member 50 improves its resistance against external shocks since the lower portion of the exterior member 50 close to the bottom surface 51c is thicker than that of the exterior member 50 of FIGS. 1 to 3.

To form the exterior member 50 including this thickened portion 51e, the outside surfaces 72a2 to 72d2 of the inside molding portion 72 of the molding jig 70 are formed to match the inner surfaces of the exterior member 50 including the thickened portion 51e. With this molding jig 70, it is possible to form the exterior member 50 with the thickened portion 51e. In addition, this exterior member 50 has such a shape that the bottom surface 51c thereof is wider than the top surface 51b thereof. Therefore, the exterior member 50 is formed from an injected exterior material more reliably.

In this connection, the shape of the thickened portion 51e is an example. The thickened portion 51e may only be formed thicker on the side closer to the bottom surface 51c than the exterior member 50 of FIGS. 1 to 3. That is, the thickened portion 51e may be formed in a stepped shape. Alternatively, the thickened portion 51e may form a discontinuous loop shape, not a continuous loop shape, in plan view.

### Modification Example 1-2

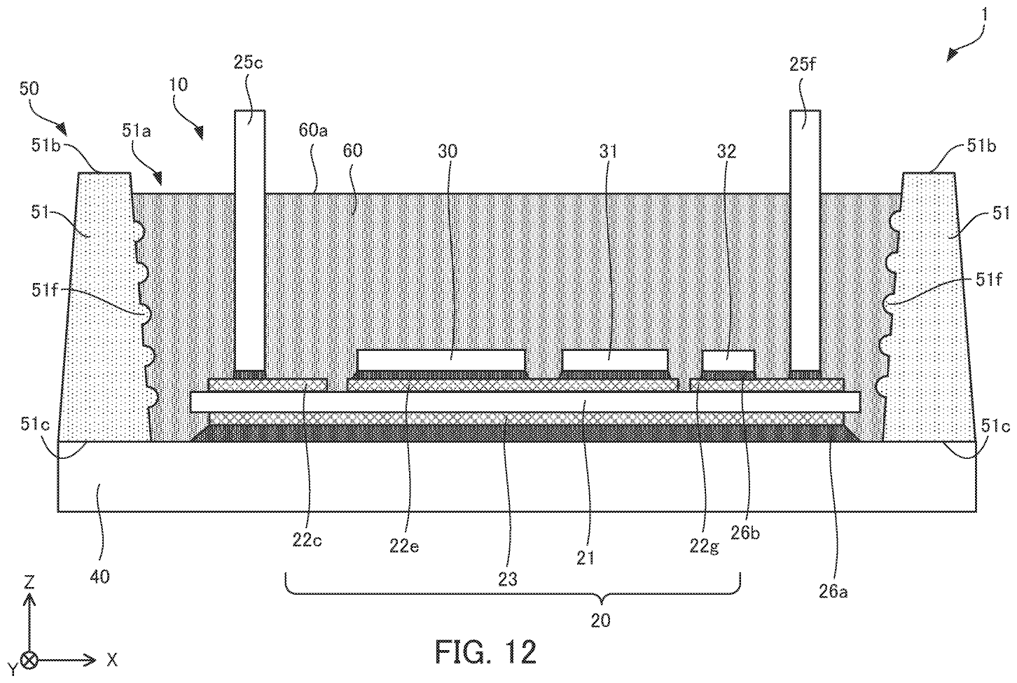

A modification example 1-2 describes an exterior member 50 different from that of FIGS. 1 to 3, with reference to FIG. 12. FIG. 12 is a sectional view of a semiconductor device according to the modification example 1-2 of the first embodiment. In this connection, as in FIG. 1, FIG. 12 corresponds to the sectional view taken along the dash-dotted line Y-Y of FIG. 3. In addition, the same reference numerals as used in the semiconductor device 1 of the first embodiment are given to the corresponding components, and the description of these components will be omitted or simplified.

A plurality of projections 51f are formed on the inner surfaces of the exterior member 50 of the semiconductor device 1 according to the modification example 1-2, unlike the inner surfaces 52a to 52d of the exterior member 50 of the semiconductor device 1 illustrated in FIGS. 1 to 3.

In this connection, FIG. 12 illustrates the case where five projections 51f are arranged in a vertical direction (in the direction from the top surface 51b toward the bottom surface 51c). The number of projections 51f is not limited thereto, but may be desirably set. In addition, a predetermined number of projections 51f are arranged in the X direction and Y direction on the inner surfaces 52a to 52d. Each projection 51f may be shaped as a hemisphere, a quadrangular pyramid, a trigonal pyramid, or a cube. Alternatively, each projection 51f may be shaped as a spine. In addition, the projections 51f may be each shaped as a stripe extending in the ±Z directions on the inner surfaces 52a to 52d and may be arranged in a loop shape on the inner surfaces 52a to 52d.

Since the plurality of projections 51f are formed on the inner surfaces 52a to 52d of the bank portion 51 in this way, the contact area between the inner surfaces 52a to 52d of the bank portion 51 and the sealing material 60 increases. In addition, the projections 51f provide an anchor effect between the bank portion 51 and the sealing material 60. Therefore, the adhesive force of the sealing material 60 to the inner surfaces 52a to 52d of the bank portion 51 is improved, and the separation of the sealing material 60 is prevented.

To form the exterior member 50 with the plurality of projections 51f, the outside surfaces 72a2 to 72d2 of the inside molding portion 72 of the molding jig 70 are formed to match the inner surfaces 52a to 52d of the exterior member 50 including the plurality of projections 51f. With this molding jig 70, it is possible to form the exterior member 50 with the plurality of projections 51f.

The plurality of projections 51f may be formed on portions of the inner surfaces 52a to 52d of the bank portion 51 corresponding to the thickened portion 51e of the modification example 1-1. This makes it possible to improve the resistance against external shocks and to prevent the separation of the sealing material 60.

### Second Embodiment

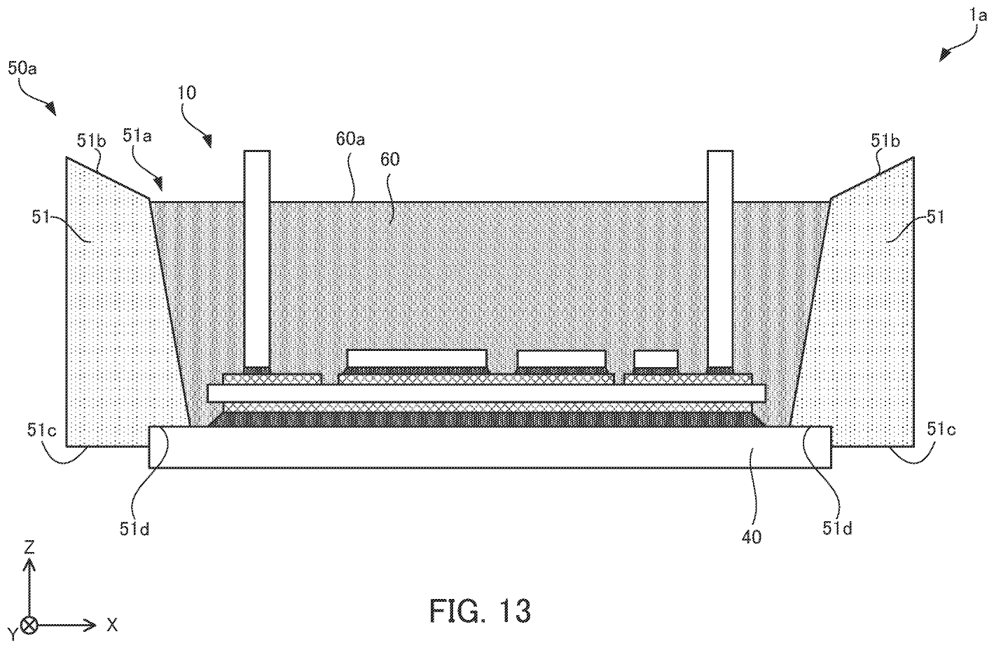

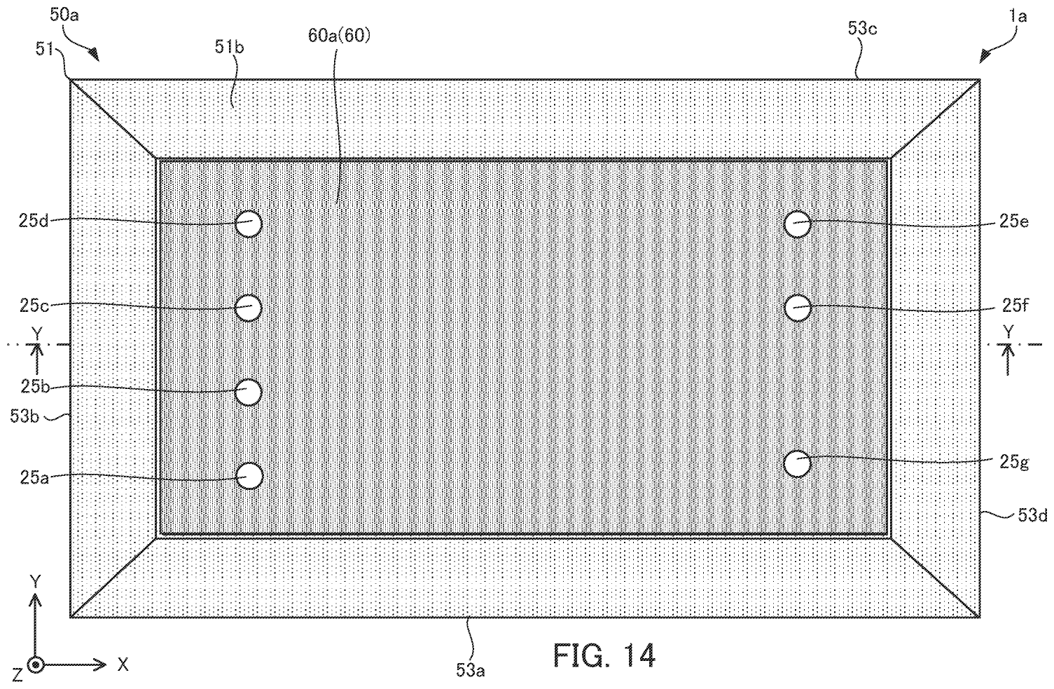

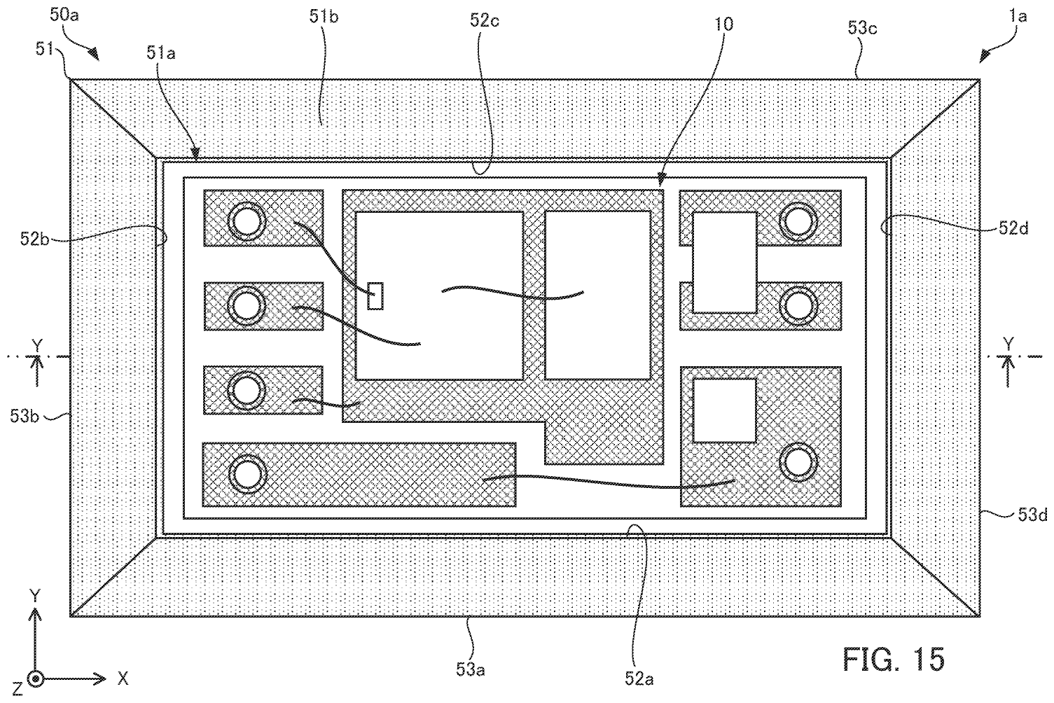

A second embodiment describes a semiconductor device including an exterior member of a different shape from the semiconductor device of the first embodiment, with reference to FIGS. 13 to 15. FIG. 13 is a sectional view of a semiconductor device according to the second embodiment. FIG. 14 is a plan view of the semiconductor device according to the second embodiment. FIG. 15 is a plan view of the semiconductor device (except a sealing material) according to the second embodiment. In this connection, FIG. 13 is a sectional view taken along the dash-dotted line Y-Y of FIGS. 14 and 15. FIG. 15 is a plan view of the semiconductor device of FIG. 14 where a sealing material 60 is removed. The same reference numerals as used in the semiconductor device 1 of the first embodiment are given to the corresponding components of the semiconductor device 1a of the second embodiment, and the description of these components will be omitted or simplified. In addition, the same reference numbers as used in the semiconductor device 1 may be omitted in the drawings relating to the second embodiment.

The semiconductor device 1a includes a base substrate 40, a semiconductor unit 10, and an exterior member 50a surrounding the semiconductor unit 10. An opening 51a of the exterior member 50a is sealed with a sealing material 60. The semiconductor unit 10 includes an insulated circuit substrate 20, semiconductor chips 30 and 31, electronic parts 32 and 33, and external connection terminals 25a to 25g. The base substrate 40, semiconductor unit 10, and sealing material 60 are the same as provided in the first embodiment.

The exterior member 50a includes a bank portion 51. The bank portion 51 has a frame shape in plan view. The bank portion 51 is made of a thermosetting resin, as in the first embodiment. The bank portion 51 includes a top surface 51b, a bottom surface 51c, inner surfaces 52a to 52d, and outer surfaces 53a to 53d. The bank portion 51 further includes a stepped portion 51d in the bottom surface 51c on the side where the inner surfaces 52a to 52d are positioned.

The top surface 51b has a continuous loop shape in plan view. The top surface 51b of the second embodiment is inclined with respect to the front surface of the base substrate 40. The top surface 51b is inclined at a more obtuse angle with respect to the front surface of the base substrate 40 than the inner surfaces 52a to 52d.

The bottom surface 51c is opposite to the top surface 51b and has a continuous loop shape in plan view. The bottom surface 51c has four portions along the base long side 40a, base short side 40b, base long side 40c, and base short side 40d of the base substrate 40. In addition, the stepped portion 51d in the bottom surface 51c is bonded to the outer periphery of the base substrate 40. The stepped portion 51d is bonded to the front surface and side surface of the base substrate 40 along the outer periphery of the base substrate 40. The stepped portion 51d is directly bonded to the base substrate 40.

The inner surfaces 52a to 52d connect the inner edge of the top surface 51b and the inner edge of the stepped portion 51d. Connecting the top surface 51b and the stepped portion 51d in this manner, the inner surfaces 52a to 52d surround a housing space 54 housing the semiconductor unit 10 on the four sides (see FIGS. 13 and 15). In addition, the inner surfaces 52a to 52d are inclined with respect to the front surface of the base substrate 40. The inclination angle here is an obtuse angle with respect to the front surface of the base substrate 40. The inner surfaces 52a to 52d are smooth without parting lines or others.

The outer surfaces 53a to 53d connect the outer edge of the top surface 51b and the outer edge of the bottom surface 51c. The outer surfaces 53a to 53d connect the top surface 51b and the bottom surface 51c in this manner (see FIGS. 13 and 15). In addition, the outer surfaces 53a to 53d are perpendicular to the front surface of the base substrate 40. In this connection, the outer surfaces 53a to 53d may be inclined at an acute angle or obtuse angle with respect to the front surface of the base substrate 40. The outer surfaces 53a to 53d are smooth without parting lines or others.

Therefore, the cross sections of the bank portion 51 in the X-Z plane and Y-Z plane become wider in the direction from the top toward the front surface of the base substrate 40 (in the −Z direction). In the second embodiment, only the inner surfaces 52a to 52d of the bank portion 51 are inclined to be wider.

In addition, the joints between the top surface 51b and each outer surface 53a to 53d of the bank portion 51 and the joints between the top surface 51b and each inner surface 52a to 52d of the bank portion 51 may be rounded or chamfered. The joints between the inner surfaces 52a to 52d do not need to have the right angle, but may be curved. Likewise, the joints between the outer surfaces 53a to 53d may be curved. Further, the joints between each inner surface 52a to 52d and the base substrate 40 may be curved.

The top surface 51b is inclined with respect to the front surface of the base substrate 40. In addition, the top surface 51b may partially be inclined or may be rough. The inner surfaces 52a to 52d and outer surfaces 53a to 53d may only be substantially smooth. The inner surfaces 52a to 52d and outer surfaces 53a to 53d may be partially inclined.

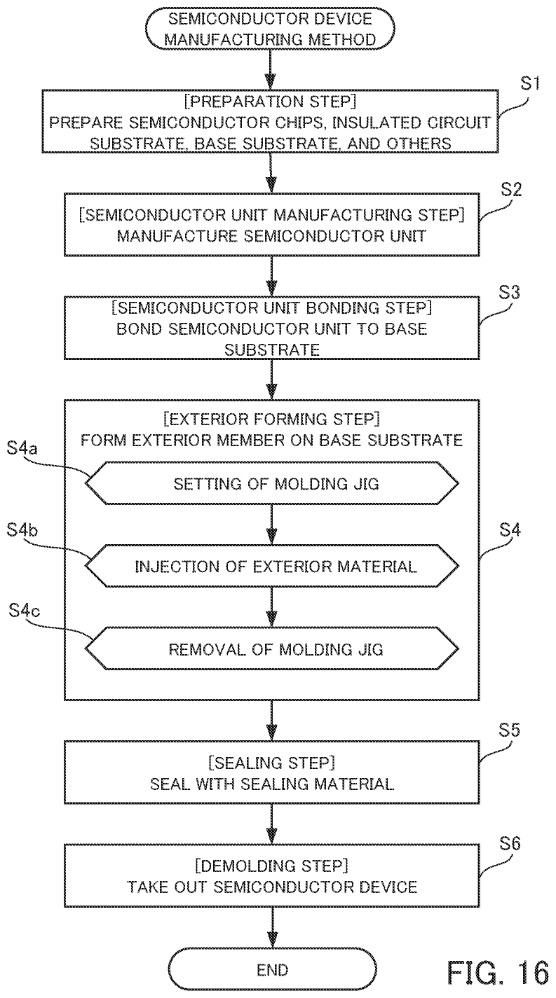

The following describes a method of manufacturing the semiconductor device 1a with reference to FIG. 16. FIG. 16 is a flowchart of a semiconductor device manufacturing method according to the second embodiment. The description of the same steps as in the first embodiment will be omitted or simplified.

First, a preparation step of preparing the components of the semiconductor device 1a (step S1), a semiconductor unit manufacturing step of manufacturing the semiconductor unit 10 (step S2), and a semiconductor unit bonding step of bonding the semiconductor unit 10 to the base substrate 40 (step S3) are executed in order.

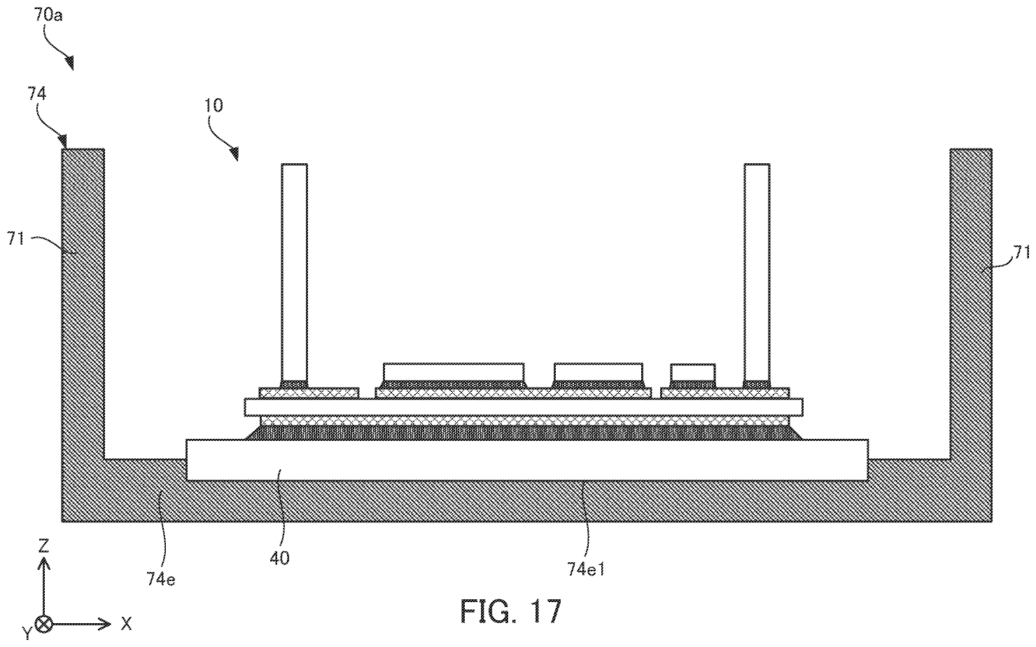

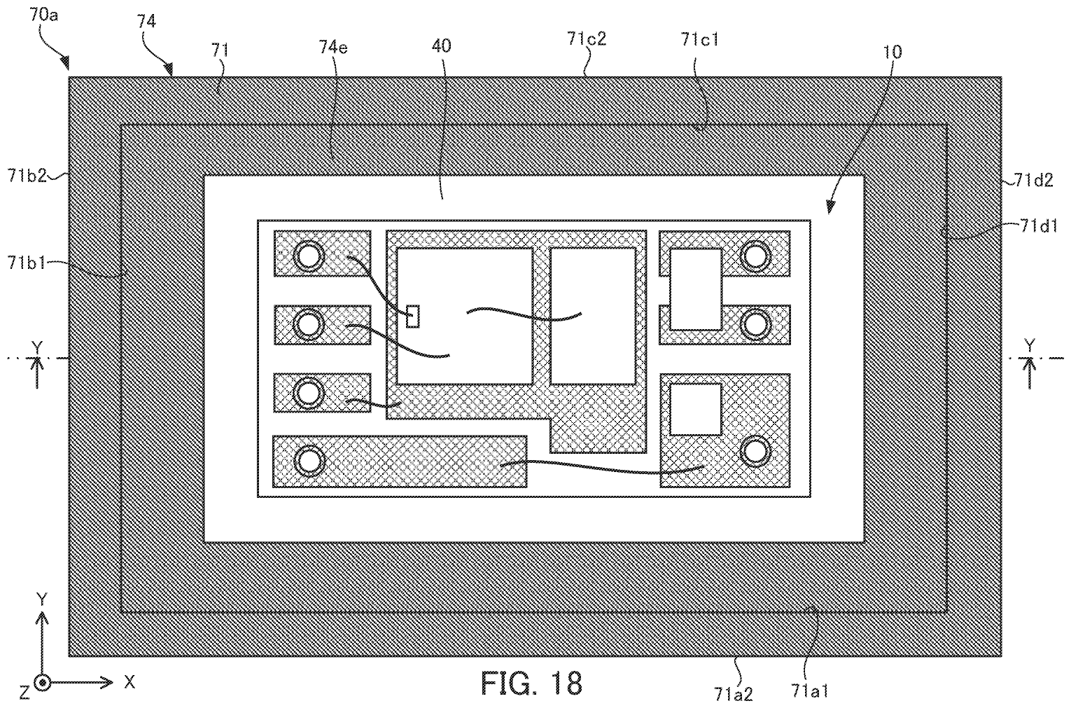

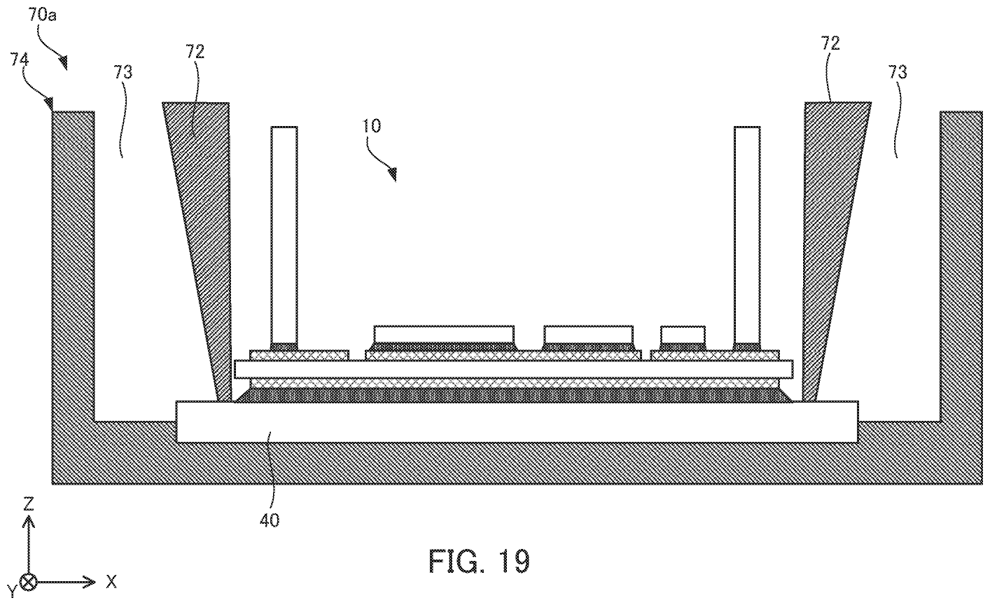

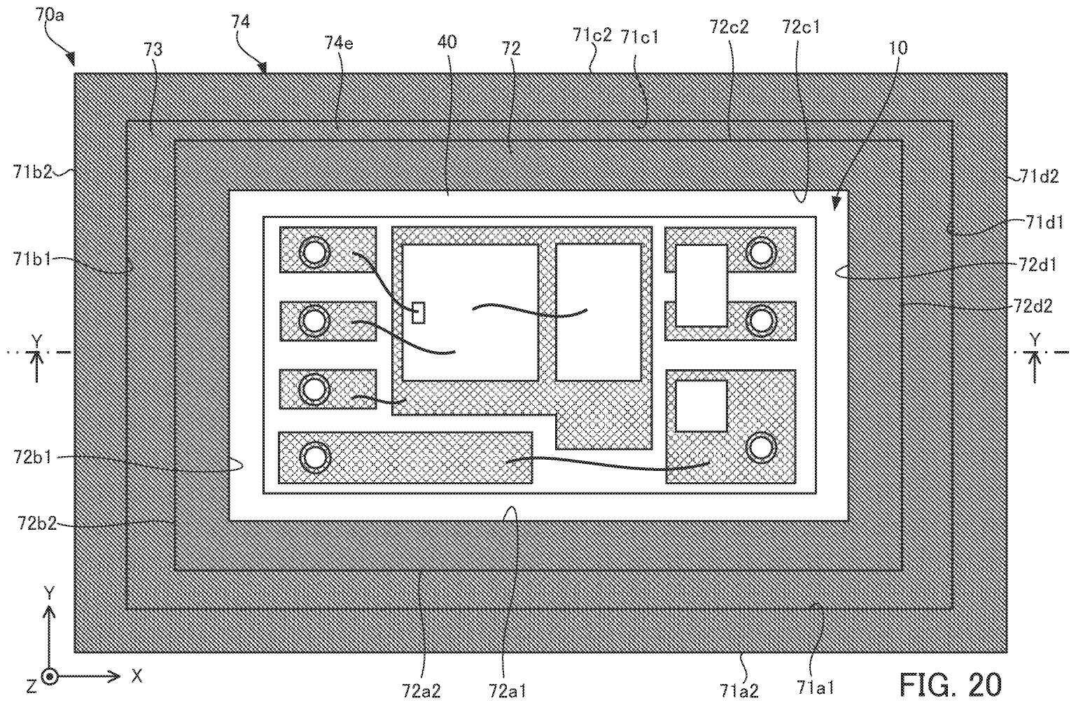

Then, an exterior forming step of forming the exterior member 50 around the semiconductor unit 10 on the base substrate 40 is executed (step S4). The exterior forming step further includes steps S4a to S4c. First, a molding jig is set on the base substrate 40 (step S4a). Step S4a will be described with reference to FIGS. 17 to 20. FIGS. 17 and 19 are sectional views illustrating the setting of the molding jig in the semiconductor device manufacturing method according to the second embodiment. FIGS. 18 and 20 are plan views illustrating the setting of the molding jig in the semiconductor device manufacturing method according to the second embodiment. In this connection, FIGS. 17 and 19 are sectional views taken along the dash-dotted line Y-Y of FIGS. 18 and 20.

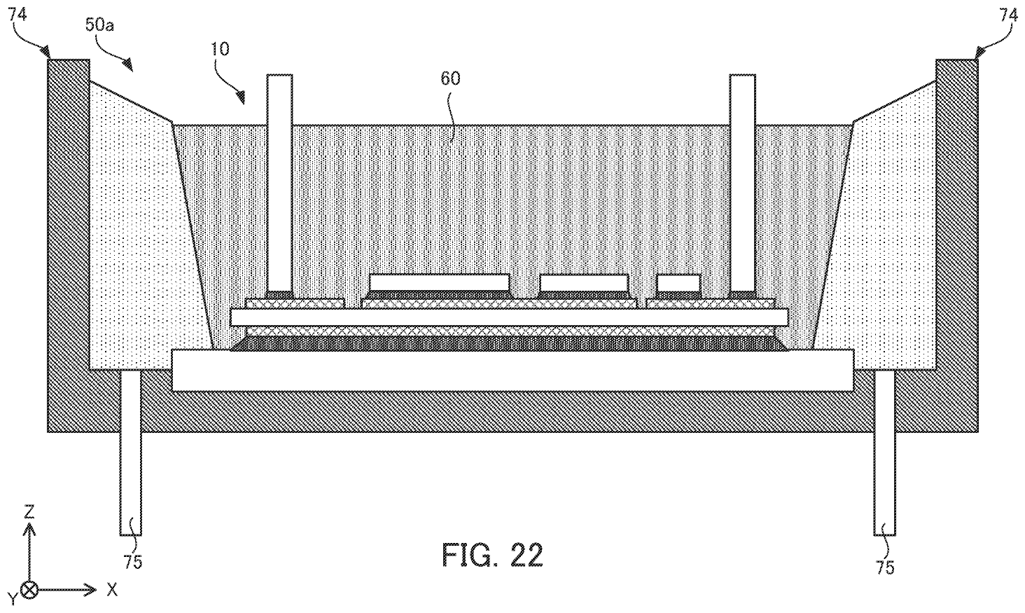

The molding jig 70a used at step S4a includes an inside molding portion 72 and an enclosure portion 74. The enclosure portion 74 has a box shape (without a lid). The enclosure portion 74 includes an outside molding portion 71, which is similar to that of the first embodiment, and a bottom portion 74e formed at the bottom of the outside molding portion 71. That is, the outside molding portion 71 is continuously formed in a loop shape so as to enclose the outer edge of the bottom portion 74e. The outside molding portion 71 is the side wall of the enclosure portion 74, and includes inside surfaces 71a1 to 71d1 and outside surfaces 71a2 to 71d2 opposite to the inside surfaces 71a1 to 71d1, as in the first embodiment. The joints between portions of the outside molding portion 71 enclosing the outer edge of the bottom portion 74e each have the right angle in plan view. More specifically, the joints between the inside surfaces 71a1 to 71d1 and the joints between the outside surfaces 71a2 to 71d2 each have the right angle in plan view. In this connection, these joints are not limited to having the right angle, but may be curved. The outside molding portion 71 is connected to the bottom portion 74e at the right angle. In other words, the outside surfaces 71a2 to 71d2 are perpendicular to the bottom portion 74e. In this case as well, their joints are not limited to having the right angle, but may be curved. A recess 74e1 is formed in the bottom portion 74e. The recess 74e1 is formed at the center of the bottom portion 74e without penetrating therethrough. In this connection, in plan view, through holes (not illustrated) though which a plurality of to-be-described columnar pressing parts 75 are to be inserted are formed between the recess 74e1 and the inside surfaces 71a1 to 71d1 of the outside molding portion 71 in the bottom portion 74e (see FIG. 22). Alternatively, a releasing agent may be applied at least to an area of the molding jig 70a that contacts a to-be-described exterior material.

In the recess 74e1 of the bottom portion 74e of the enclosure portion 74, the semiconductor unit 10 (base substrate 40) is set as illustrated in FIGS. 17 and 18. At this time, the lower portion of the side surface of the base substrate 40 of the semiconductor unit 10 fits the recess 74e1.

Then, the inside molding portion 72 is set between the outside molding portion 71 of the enclosure portion 74 and the semiconductor unit 10 on the base substrate 40. As in the first embodiment, the inside molding portion 72 has a frame shape and includes inside surfaces 72a1 to 72d1 and outside surfaces 72a2 to 72d2. At this time, the outside surfaces 72a2 to 72d2 match the inner edge of the molding space 73.

In the second embodiment, the inside surfaces 72a1 to 72d1 are provided along the base long side 40a, base short side 40b, base long side 40c, and base short side 40d, and extend vertically upward with respect to the front surface of the base substrate 40. Therefore, the inside surfaces 72a1 to 72d1 surround the semiconductor unit 10 on the four sides. The inside surfaces 72a1 to 72d1 may be perpendicular to the base substrate 40 or may be inclined with respect to the base substrate 40.

The outside surfaces 72a2 to 72d2 are opposite to the inside surfaces 72a1 to 72d1. The outside surfaces 72a2 to 72d2 are provided along the base long side 40a, base short side 40b, base long side 40c, and base short side 40d, and extend upward with respect to the base substrate 40. The outside surfaces 72a2 to 72d2 are inclined at an acute angle with respect to the base substrate 40. The joints between the outside surfaces 72a2 to 72d2 may be rounded or chamfered.

In the manner described above, the molding space 73 is continuously formed in a loop shape along the outer periphery of the base substrate 40. In this connection, the height of the molding jig 70a may only be set greater than a desired height of the exterior member 50a.

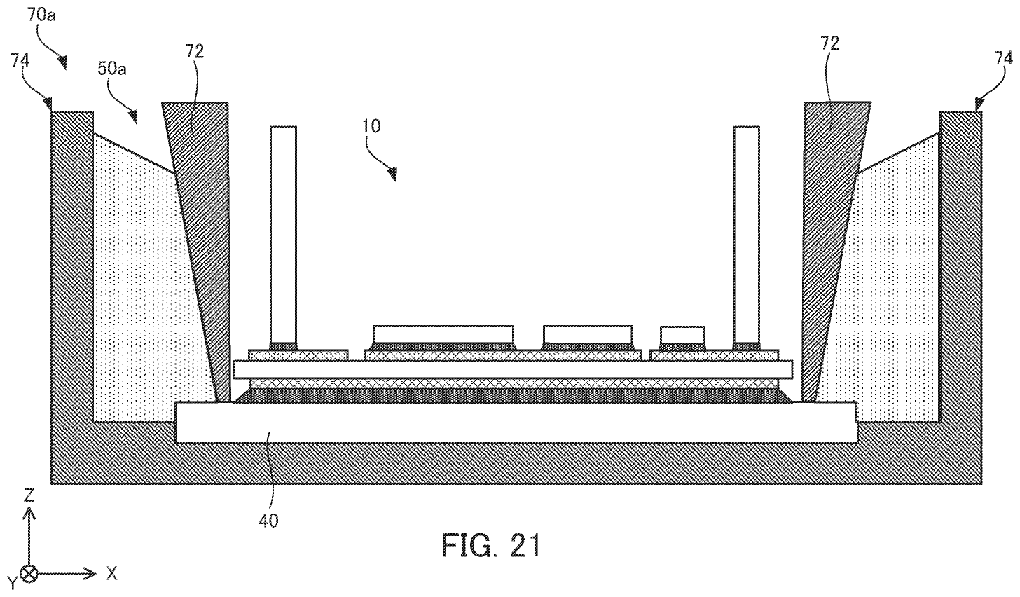

Then, the exterior material is injected in the molding jig 70a (step S4b). Step S4b will be described with reference to FIG. 21. FIG. 21 is a sectional view illustrating the injection of the exterior material in the semiconductor device manufacturing method according to the second embodiment. FIG. 21 is a sectional view taken along the dash-dotted line Y-Y of FIG. 20 in a situation where with the exterior material is injected.

The exterior material is injected into the molding space 73 of the molding jig 70a attached at step S4a. The exterior material has the same component as the exterior member 50a. The exterior material tends to descend due to its weight, as described earlier. The exterior material fills the molding space 73 without air voids as illustrated in FIG. 21. In this case as well, the outside surfaces 72a2 to 72d2 of the inside molding portion 72 are inclined at the acute angle with respect to the front surface of the base substrate 40. The exterior material stably fills the molding space 73 that becomes wider toward the base substrate 40. Therefore, the exterior material filling the molding space 73 is solidified reliably. The exterior member 50a obtained by the solidification is hard and stable. In addition, the injected exterior material adheres to the base substrate 40 as it is. The exterior member 50a formed in the manner described above is directly bonded to the base substrate 40. It is possible that the exterior member 50a has a different shape from that in the first embodiment, according to the shape of the molding jig 70a.

Then, the molding jig 70a is removed (step S4c). After the exterior material filling the molding space 73 is solidified to become the exterior member 50a, the molding jig 70a is removed. However, in the second embodiment, only the inside molding portion 72 of the molding jig 70a is removed. The outside surfaces 72a2 to 72d2 of the inside molding portion 72 of the molding jig 70a are transcribed to the inner surfaces 52a to 52d of the exterior member 50a formed in this way. Therefore, the inner surfaces 52a to 52d of the exterior member 50a are smooth without parting line or others. In addition, the exterior member 50a formed in this manner is directly bonded to the base substrate 40.

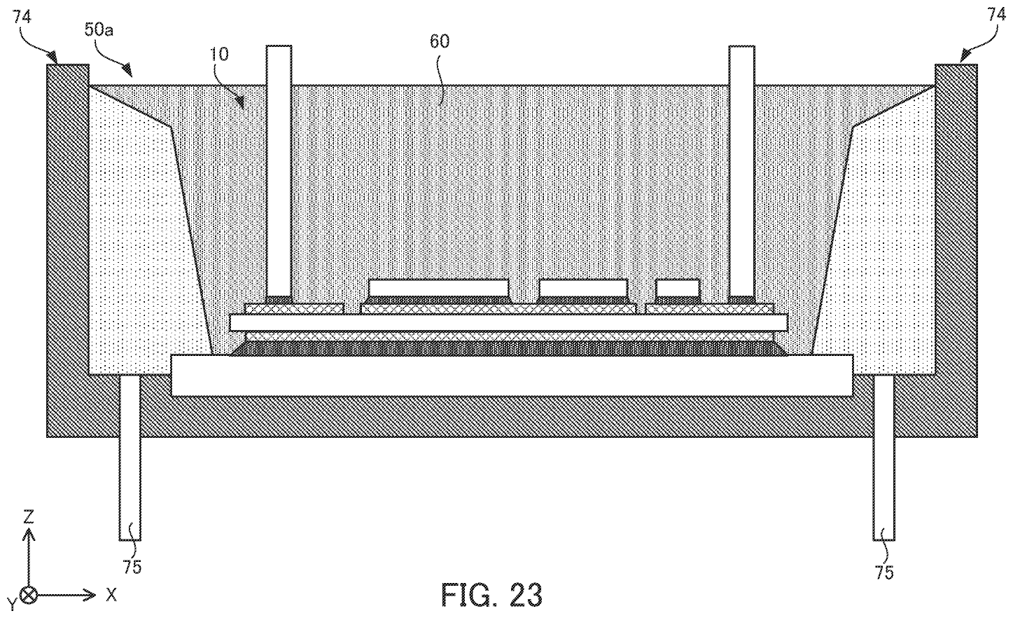

Then, a sealing step of sealing with the sealing material 60 is executed (step S5). Step S5 and subsequent step S6 will be described with reference to FIGS. 22 and 23. FIGS. 22 and 23 are sectional views illustrating the sealing step and a demolding step in the semiconductor device manufacturing method according to the second embodiment. The sealing material 60 is injected into the housing space 54 of the exterior member 50a formed at step S4. In this connection, the sealing material 60 is injected to fill up to just below the inclined top surface 51b of the exterior member 50a. Thereby, the semiconductor unit 10 surrounded by the exterior member 50a is sealed (see FIG. 22). Since the top surface 51b of the exterior member 50a is inclined, the filling sealing material 60 is unlikely to flow from the exterior member 50a. Alternatively, since the top surface 51b of the exterior member 50a is inclined, the sealing material 60 may be injected to cover the top surface 51b of the exterior member 50a as much as possible so that the front surface (sealing front surface 60a) of the semiconductor device 1a is level (see FIG. 23).

Then, the demolding step of taking out the semiconductor device 1 from the molding jig 70a is executed (step S6). The demolding step will be described with reference to FIG. 22. FIG. 22 is a sectional view illustrating the demolding step in the semiconductor device manufacturing method according to the second embodiment. In this connection, FIG. 22 is a sectional view corresponding to FIG. 21.

After the exterior member 50a is formed, pressing parts 75 are inserted into the bottom portion 74e of the enclosure portion 74 from the rear surface side thereof toward the inside of the enclosure portion 74, as illustrated in FIG. 22. In this connection, the pressing parts 75 are respectively inserted at the four corners in the bottom portion 74e, for example. The pressing parts 75 may each have a columnar shape, a prismatic shape, or a columnar shape. In this connection, in the case illustrated in FIG. 23 as well, the pressing parts 75 are inserted as in the case of FIG. 22.

The pressing parts 75 press the semiconductor device 1a in the outside molding portion 71 upward (in the +Z direction). The outer surfaces 53a to 53d of the exterior member 50a are perpendicular to the front surface of the base substrate 40. Therefore, the semiconductor device 1a is smoothly taken out of the enclosure portion 74. By doing so, the semiconductor device 1a illustrated in FIGS. 13 and 14 is obtained. In the case of FIG. 23 as well, the semiconductor device 1a illustrated in FIGS. 13 and 14 in which the front surface thereof is level is obtained.

In the above semiconductor device 1a, the exterior member 50a, as a substitute for a case, is formed without using a mold-releasing sheet. In addition, holes for making a vacuum do not need to be formed, and a vacuum step or vacuum device are not needed accordingly. It is possible to form the exterior member 50a at a predetermined position on the base substrate 40 with precision. The exterior member 50a is directly bonded to the base substrate 40. Therefore, an additional adhesive member, which may be needed if a case is used, is not needed, and an application step of applying the adhesive material is not needed accordingly. As a result, the semiconductor device 1a without a case is manufactured at reduced cost.

The disclosed techniques make it possible to manufacture a semiconductor device without a case at reduced cost.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a substrate having a mounting area on a front surface thereof;
a semiconductor chip disposed in the mounting area;
an exterior member having a bottom surface bonded to the front surface of the substrate, the exterior member continuously surrounding the mounting area in a loop shape in a plan view of the semiconductor device, to thereby enclose a housing space, the mounting area being in the housing space; and
a sealing material sealing the housing space.

2. The semiconductor device according to claim 1, wherein the exterior member has an inner surface that surrounds the housing space, the inner surface of the exterior member being inclined at an obtuse angle with respect to the front surface of the substrate.

3. The semiconductor device according to claim 2, wherein the exterior member has a top surface opposite to the bottom surface, the top surface being inclined at another obtuse angle with respect to the front surface of the substrate, said another obtuse angle being larger than the obtuse angle.

4. The semiconductor device according to claim 3, wherein the top surface of the exterior member is sealed by the sealing material sealing the housing space.

5. The semiconductor device according to claim 2, wherein the inner surface of the exterior member has a plurality of projections formed thereon.

6. The semiconductor device according to claim 1, wherein the exterior member has a top surface opposite to the bottom surface, the top surface being higher, in a depth direction of the semiconductor device, than a front surface of the sealing material sealing the housing space.

7. The semiconductor device according to claim 1, wherein the bottom surface of the exterior member is bonded to the front surface of the substrate at an outer periphery thereof, so that the exterior member projects outward from the outer periphery.

8. The semiconductor device according to claim 1, wherein the exterior member has an inner surface that surrounds the housing space, the inner surface has a first portion and a second portion that is opposite to the first portion and that is positioned closer to the bottom surface than the first portion, and the second surface projects more toward the substrate than the first portion.

9. The semiconductor device according to claim 1, wherein the exterior member has a thermosetting resin as a principal component thereof.

10. The semiconductor device according to claim 9, wherein the sealing material and the exterior member have the same principal component.

11. The semiconductor device according to claim 1, wherein the exterior member has an outer surface that is entirely smooth.

12. A method of manufacturing a semiconductor device, comprising:
preparing a substrate having a semiconductor chip disposed in a mounting area that is on a front surface of the substrate;
forming an exterior member on the substrate such that
the exterior member continuously surrounds the mounting area in a loop shape in a plan view of the semiconductor device, to thereby enclose a housing space, the mounting area being in the housing space, and
a bottom surface of the exterior member is bonded to the front surface of the substrate; and
sealing the housing space with a sealing material.

13. The method of manufacturing the semiconductor device according to claim 12, wherein the exterior member is made of a thermosetting resin.

14. The method of manufacturing the semiconductor device according to claim 13, wherein the forming of the exterior member includes
setting a molding jig to define an inner edge and an outer edge of a molding space where the exterior member is to be formed on the substrate, and
injecting the thermosetting rein into the molding space to form the exterior member.

15. The method of manufacturing the semiconductor device according to claim 14, wherein the molding jig includes an inside molding portion and an outside molding portion, the inside molding portion having an outside surface along the inner edge of the molding space for forming the exterior member on the substrate, the outside molding portion having an inside surface along the outer edge of the molding space for forming the exterior member on the substrate.

16. The method of manufacturing the semiconductor device according to claim 15, wherein the outside surface of the inside molding part is inclined at an acute angle with respect to the front surface of the substrate.

17. The method of manufacturing the semiconductor device according to claim 16, wherein the inside surface of the outside molding portion is positioned on an outer edge of the substrate.

18. The method of manufacturing the semiconductor device according to claim 16, wherein
the outside molding portion includes a bottom portion, and the substrate is positioned on the bottom portion, and
the inside surface of the outside molding portion is positioned outside an outer edge of the substrate.

19. The method of manufacturing the semiconductor device according to claim 18, the inside surface of the outside molding portion is positioned perpendicular to the front surface of the substrate.
